(19) United States
(12) Patent Application Publication
(10) Pub. No.: US 2025/0087970 A1
(43) Pub. Date: Mar. 13, 2025

(54) SEMICONDUCTOR APPARATUS

(71) Applicant: Mitsubishi Electric Corporation, Tokyo (JP)

(72) Inventor: Nobuyuki OGAWA, Tokyo (JP)

(73) Assignee: Mitsubishi Electric Corporation, Tokyo (JP)

(21) Appl. No.: 18/723,091

(22) PCT Filed: Mar. 17, 2022
(86) PCT No.: PCT/JP2022/012234

§ 371 Date: Jun. 21, 2024

(51) Int. Cl. H01S 5/22; H01S 5/343

(52) U.S. Cl. CPC H01S 5/2205; H01S 5/2202; H01S 5/34306

(57) ABSTRACT

A semiconductor apparatus includes a ridge portion formed on a semiconductor substrate and having a lower-side clad layer, an MQW portion formed and an upper-side clad layer; a blocking layer on both sides of the ridge portion; and a contact layer formed on the upper-side clad layer, wherein in a semiconductor layer that is formed with the semiconductor substrate, the blocking layer, and the contact layer, at least layers of the first conductivity type, the second conductivity type, the first conductivity type, and the second conductivity type are laminated from a lower side, first two grooves are formed in a composite layer that is formed with layers from the blocking layer to the contact layer, and the contact layer on the ridge portion and the contact layer interposed between the first two grooves are connected together by a first electrode.

### FIELD

The present disclosure relates to a semiconductor apparatus and particularly to a semiconductor apparatus in which electrostatic discharge (ESD) breakdown resistance is improved.

### BACKGROUND

There is a possibility that a semiconductor apparatus is damaged by ESD. In an integrated circuit, ESD breakdown resistance can be enhanced by incorporating a protection circuit, but a discrete device such as a semiconductor laser device has to depend on the ESD breakdown resistance of the device itself.

PTL 1 discloses a semiconductor laser device in which separately from a resonator portion, a p-type/i-type/p-type structure is formed in a case of a p-type substrate, an n-type/i-type/n-type structure is formed in a case of an n-type substrate, and the ESD breakdown resistance is improved by using those structures.

### CITATION LIST

### Patent Literature

[PTL 1] JP 2010-287604 A

### SUMMARY

### Technical Problem

However, in the above-described semiconductor laser device, a semiconductor layer has to be separately formed for making the above structure, and an increase in man-hours cannot be avoided.

The present disclosure has been made to solve the above problems, and an object thereof is to obtain a semiconductor apparatus in which ESD breakdown resistance is improved without increasing man-hours.

### Solution to Problem

A semiconductor apparatus according to the present disclosure includes a semiconductor substrate of a first conductivity type, on a back surface of which a back surface electrode is formed; a ridge portion that is formed on a front surface of the semiconductor substrate and that has a lower-side clad layer of the first conductivity type, an MQW portion formed on the lower-side clad layer, and an upper-side clad layer of a second conductivity type that is formed on the MQW portion; a blocking layer that is embedded on the semiconductor substrate on both sides of the ridge portion; and a contact layer that is formed on the upper-side clad layer that is further formed above the ridge portion and the blocking layer, wherein in a semiconductor layer that is formed with the semiconductor substrate, the blocking layer, and the contact layer, at least layers of the first conductivity type, the second conductivity type, the first conductivity type, and the second conductivity type are laminated from a lower side, first two grooves are formed in a composite layer that is formed with layers from the blocking layer to the contact layer, and the contact layer on the ridge portion and the contact layer interposed between the first two grooves are connected together by a first electrode.

A semiconductor apparatus according to the present disclosure includes A semiconductor apparatus comprising: a semiconductor substrate of a first conductivity type, on a back surface of which a back surface electrode is formed; a ridge portion that is formed on a front surface of the semiconductor substrate and that has a lower-side clad layer of the first conductivity type, an MQW portion formed on the lower-side clad layer, and an upper-side clad layer of a second conductivity type that is formed on the MQW portion; a blocking layer that is embedded on the semiconductor substrate on both sides of the ridge portion; and a contact layer that is formed on the upper-side clad layer that is further formed above the ridge portion and the blocking layer, wherein in a semiconductor layer that is formed with the semiconductor substrate, the blocking layer, and the contact layer, at least layers of the first conductivity type, the second conductivity type, the first conductivity type, and the second conductivity type are laminated from a lower side, first two grooves are formed in a composite layer that is formed with layers from the blocking layer to the contact layer, second two grooves are formed in the composite layer, the contact layer on the ridge portion and a first region of the contact layer interposed between the second two grooves are connected together by a first electrode, and a second region of the contact layer interposed between the second two grooves and the contact layer interposed between the first two grooves are connected together by a second electrode.

### Advantageous Effects of Invention

According to the present disclosure, a semiconductor apparatus can be obtained in which ESD breakdown resistance is improved without increasing man-hours.

### BRIEF DESCRIPTION OF DRAWINGS

FIG. 1 is a perspective view of a semiconductor apparatus according to the first embodiment.

FIG. 2 is a cross-sectional view of the semiconductor apparatus according to the first embodiment.

FIG. 3 is a cross-sectional view showing the method for manufacturing the semiconductor apparatus according to the first embodiment.

FIG. 4 is a cross-sectional view showing the method for manufacturing the semiconductor apparatus according to the first embodiment.

FIG. 5 is a cross-sectional view showing the method for manufacturing the semiconductor apparatus according to the first embodiment.

FIG. 6 is a cross-sectional view showing the method for manufacturing the semiconductor apparatus according to the first embodiment.

FIG. 7 is a cross-sectional view showing the method for manufacturing the semiconductor apparatus according to the first embodiment.

FIG. 8 is a cross-sectional view showing the method for manufacturing the semiconductor apparatus according to the first embodiment.

FIG. 9 is a perspective view of a semiconductor apparatus according to the second embodiment.

FIG. 10 is a cross-sectional view of the semiconductor apparatus according to the second embodiment.

FIG. 11 is a cross-sectional view of the semiconductor apparatus according to the third embodiment.

FIG. 12 is a cross-sectional view of the semiconductor apparatus according to the fourth embodiment.

### DESCRIPTION OF EMBODIMENTS

### First Embodiment

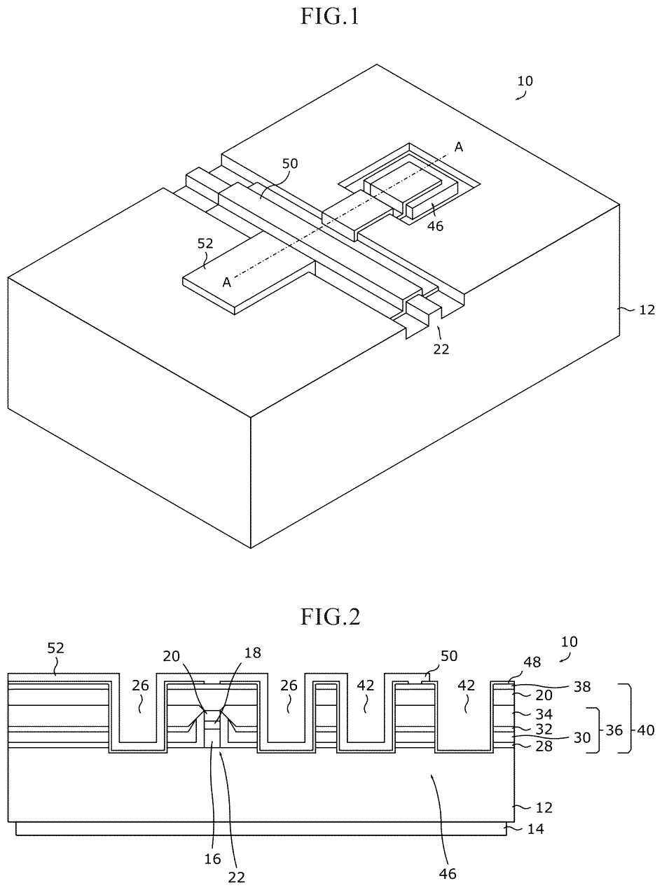

A semiconductor apparatus 10 according to a first embodiment is a distributed feedback (DFB) semiconductor laser device. A perspective view of the semiconductor apparatus 10 is illustrated in FIG. 1. A cross-sectional view taken along A-A in FIG. 1 is illustrated in FIG. 2. Note that in the drawings including those, dimensions and scales of portions might be different among the drawings.

The semiconductor apparatus 10 includes a semiconductor substrate 12. The semiconductor substrate 12 is formed of p-type InP. A back surface electrode 14 is formed on a back surface of the semiconductor substrate 12.

A ridge portion 22 is formed on a front surface of the semiconductor substrate 12. The ridge portion 22 has a lower-side clad layer 16, an MQW portion 18 formed on the lower-side clad layer 16, and an upper-side clad layer 20 formed on the MQW portion 18. The lower-side clad layer 16 is formed of p-type InP. The MQW portion 18 is formed of InP and includes a multiple quantum well (MQW). The upper-side clad layer 20 is formed of n-type InP. The ridge portion 22 is a resonator in which laser light resonates.

Blocking layers 36 are embedded on both sides of the ridge portion 22. The blocking layers 36 are embedded on the semiconductor substrate 12 on both sides of the ridge portion 22, and in an order from a lower side, a first semiconductor layer 28 of a first conductivity type, a second semiconductor layer 30 of a second conductivity type, an i-type semiconductor layer 32 of an i-type, and a third semiconductor layer 34 of the first conductivity type are laminated. Here, an i-type semiconductor layer denotes a semiconductor layer in which no carrier is implanted. Each of those layers is formed of InP. The blocking layer 36 is a current constriction layer for causing a current to flow only in the ridge portion 22. Note that the i-type semiconductor layer 32 may be omitted. Further, the i-type semiconductor layer may be inserted between any layers that constitute the blocking layer 36. This layer to be inserted may be the i-type semiconductor layer that is doped with Fe.

On the upper-side clad layer 20 that is further formed above the ridge portion 22 and the blocking layer 36, a contact layer 38 in which n-type InP and n-type InGaAs are laminated is formed.

In the blocking layers 36 on left and right of the ridge portion 22, two grooves 26 are dug such that the ridge portion 22 is interposed between those. Those grooves 26 allow the ridge portion 22 to be electrically isolated from other portions.

First two grooves 42 are formed in a composite layer 40 formed with the layers from the blocking layer 36 to the contact layer 38. A semiconductor layer from the contact layer 38 to the semiconductor substrate 12 in a region interposed between the first two grooves 42 is a voltage clamping portion 46 for clamping voltage. It is sufficient that in the above semiconductor layer, in an order from the lower side, at least layers of a p-type, an n-type, the p-type, and the n-type are laminated. In the present embodiment, the first semiconductor layer 28 is the p-type, the second semiconductor layer 30 is the n-type, the third semiconductor layer 34 is the p-type, and the contact layer 38 is the n-type. Note that one of the two grooves 26 and one of the first two grooves 42 may be the same groove.

An insulation film 48 is formed on the contact layers 38 and the grooves. The insulation film 48 has openings on the ridge portion 22 and the voltage clamping portion 46.

The contact layer 38 interposed between the first two grooves 42 and the contact layer 38 on the ridge portion 22 are connected together by a first electrode 50. Further, a lower portion of the voltage clamping portion 46 interposed between the first two grooves 42 and a lower portion of the ridge portion 22 are electrically connected together via the back surface electrode 14. Thus, the voltage clamping portion 46 and the ridge portion 22 are connected electrically in parallel. The first electrode 50 is connected with a pad electrode 52.

Because the voltage clamping portion 46 and the ridge portion 22 are connected electrically in parallel as described above, even when ESD is applied to the ridge portion 22, an excessive electric charge at a certain level or higher mainly flows through the voltage clamping portion 46 having a voltage clamping function.

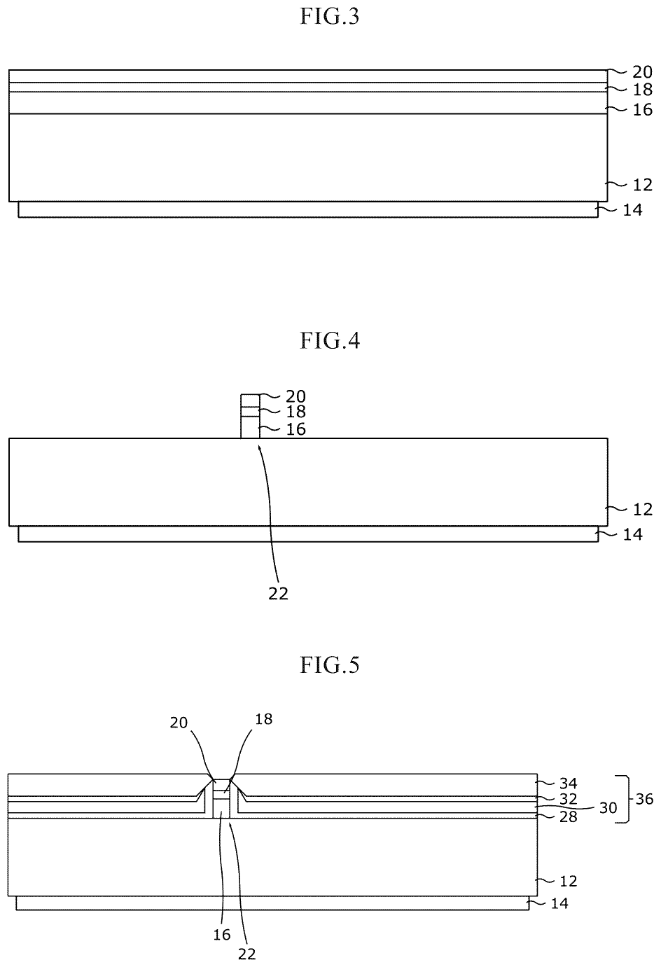

A method for manufacturing the semiconductor apparatus 10 will hereinafter be described. First, as in FIG. 3, on the semiconductor substrate 12 on whose back surface the back surface electrode 14 is formed, the lower-side clad layer 16, the MQW portion 18, and the upper-side clad layer 20 are sequentially formed.

Next, as in FIG. 4, the upper-side clad layer 20 to the lower-side clad layer 16 are etched while the ridge portion 22 is left.

Next, as in FIG. 5, the blocking layers 36 are embedded on both sides of the ridge portion 22.

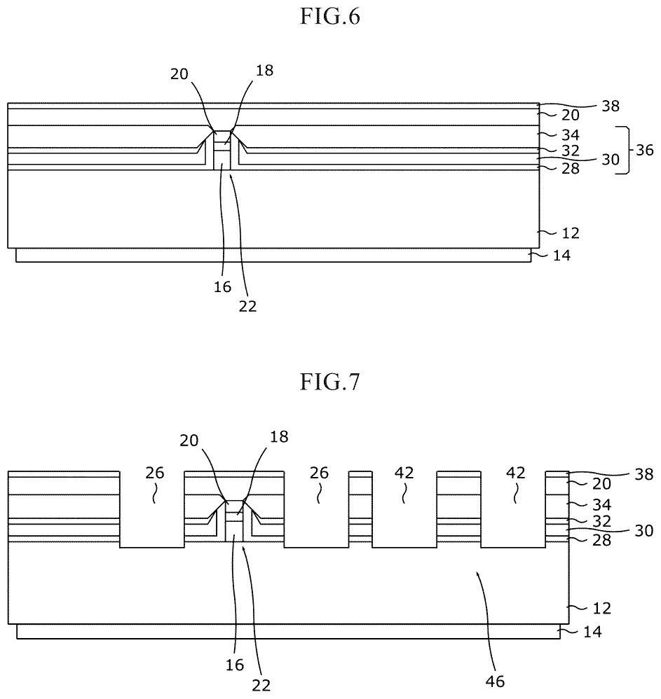

Next, as in FIG. 6, the upper-side clad layer 20 and the contact layer 38 are formed on the ridge portion 22 and the blocking layers 36.

Next, as in FIG. 7, the grooves are formed by etching on both sides of the ridge portion 22 and of the voltage clamping portion 46. The first two grooves 42 are formed in this step.

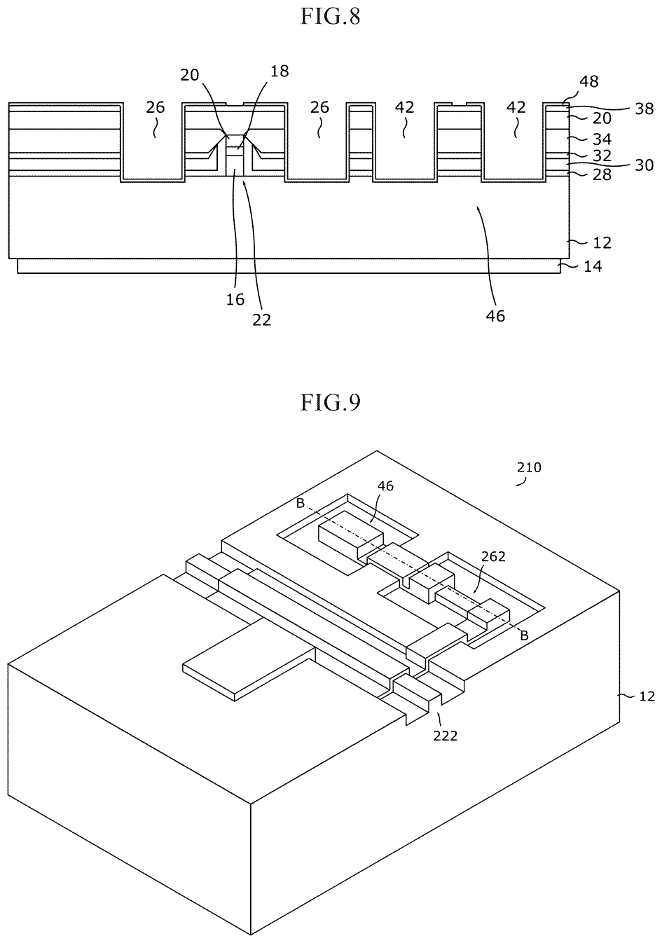

Next, as in FIG. 8, the insulation film 48 is formed on the contact layers 38 and the grooves.

Next, the first electrode 50 is formed. When this step is finished, the semiconductor apparatus 10 in FIG. 1 is formed.

As described above, according to the present embodiment, because the voltage clamping portion and the ridge portion 22 are connected electrically in parallel, the ridge portion 22 can be protected from the ESD, and ESD breakdown resistance of the semiconductor apparatus can be improved.

Further, the voltage clamping portion is formed by using the contact layer, the blocking layer as the current constriction layer, and the semiconductor substrate, and the first two grooves are simultaneously formed with the grooves on the left and right of the ridge portion. Thus, man-hours are not increased.

### Second Embodiment

Differently from the first embodiment, in a semiconductor apparatus 210 according to the second embodiment, a resistor portion 262 is connected between a ridge portion 222 and the voltage clamping portion 46.

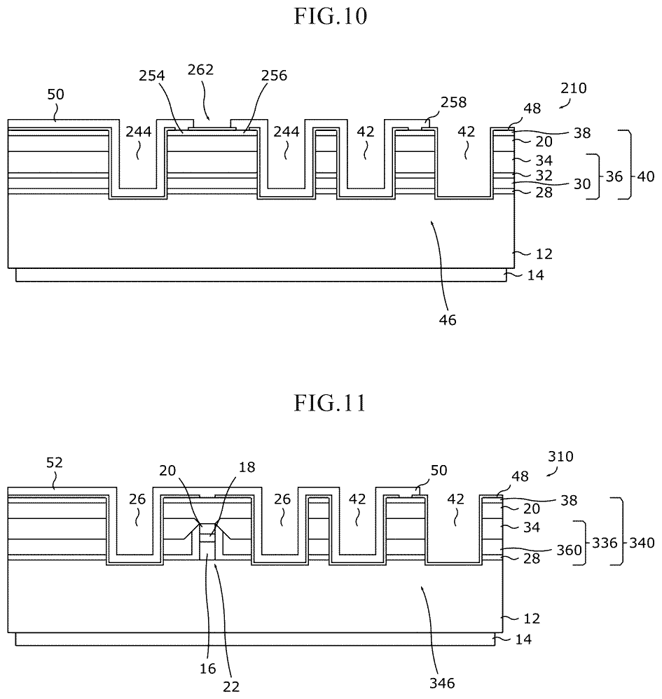

A perspective view of the semiconductor apparatus 210 is illustrated in FIG. 9. A cross-sectional view taken along B-B in FIG. 9 is illustrated in FIG. 10.

Second two grooves 244 are formed in the composite layer 40. The composite layer 40 interposed between the second two grooves is the resistor portion 262. End portions of the resistor portion 262 are a first region 254 and a second region 256 of the contact layer 38 interposed between the second two grooves 244. Note that one of the first two grooves 42 and one of the second two grooves 244 may be the same groove.

The contact layer 38 on the ridge portion 222 and the first region 254 are connected together by the first electrode 50, and the second region 256 and the contact layer 38 interposed between the first two grooves 42 are connected together by a second electrode 258. That is, the resistor portion 262 is connected between the ridge portion 222 and the voltage clamping portion 46.

As described above, according to the present embodiment, because the resistor portion is connected between the ridge portion and the voltage clamping portion, the ESD breakdown resistance of the semiconductor apparatus can further be improved.

Further, the resistor portion is formed by using the contact layer to the blocking layer as the current constriction layer, and the second two grooves are simultaneously formed with the grooves on the left and right of the ridge portion. Thus, man-hours are not increased.

### Third Embodiment

Differently from the first embodiment, in a semiconductor apparatus 310 according to the third embodiment, an i-type semiconductor layer that constitutes a blocking layer 336 is removed, and the second semiconductor layer is replaced by an i-type semiconductor layer 360 that is doped with Fe. A cross-sectional view of the semiconductor apparatus 310 is illustrated in FIG. 11.

When a voltage clamping portion 346 is caused to have such a structure, a working of clamping a voltage is also provided, and similar effects to those of the first embodiment are provided. In addition, the i-type semiconductor layer 360 is doped with Fe, and an effect of current constriction is thereby enhanced.

### Fourth Embodiment

Differently from the first embodiment, in a semiconductor apparatus according to the fourth embodiment, an electro-absorption (EA) modulator portion (EA portion 464) is connected with a DFB portion. A basic configuration of the EA portion 464 is similar to that of the DFB portion, and laser light produced in the DFB portion is modulated by a voltage provided to an EA electrode 466. Specifically, the laser light produced in the ridge portion of the DFB portion is modulated in a ridge portion 422 of the EA portion 464.

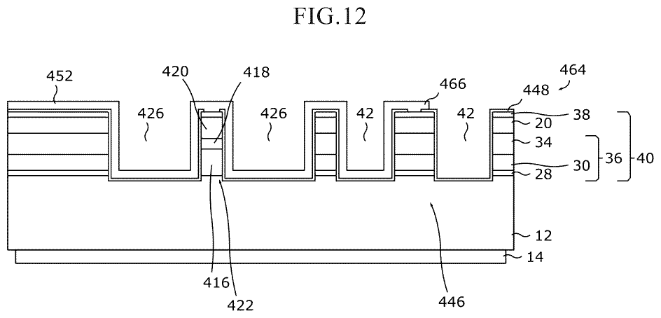

A cross-sectional view of the EA portion 464 is illustrated in FIG. 12. Differently from the DFB portion, in the EA portion 464, side surfaces of the ridge portion 422 are covered by an insulation film 448.

In the EA portion 464, a voltage clamping portion 446 also provides the working of clamping the voltage, and similar effects to those of the first embodiment are provided.

Note that for example, in the first embodiment, the semiconductor substrate is set as the p-type, and the contact layer is set as the n-type; however, the semiconductor substrate may be set as the n-type, and the contact layer may be set as the p-type. The same applies to the other semiconductor layers. To indicate that p-n switching is possible as described above, for example, it can be expressed that the semiconductor substrate is the first conductivity type and the contact layer is the second conductivity type. This indicates either one of the fact that the first conductivity type is the p-type and the second conductivity type is the n-type and the fact that the first conductivity type is the n-type and the second conductivity type is the p-type. The fact that the p-n switching is possible and the fact that expressions of the first conductivity type and the second conductivity type are possible can apply to all of the embodiments.

Further, features according to the embodiments may be used in combination.

### REFERENCE SIGNS LIST

10,210,310 semiconductor apparatus, 12 semiconductor substrate, 14 back surface electrode, 16,416 lower-side clad layer, 18,418 MQW portion, 20,420 upper-side clad layer, 22,222,422 ridge portion, 26,426 groove, 28 first semiconductor layer, 30 second semiconductor layer, 32,360 i-type semiconductor layer, 34 third semiconductor layer, 36,336 blocking layer, 38 contact layer, 40 composite layer, 42 first two groove, 244 second two groove, 46,346,446 voltage clamping portion, 48,448 insulation film, 50 first electrode, 52,452 pad electrode, 254 first region, 256 second region, 258 second electrode, 262 resistor portion 464 EA portion, 466 EA electrode

1. A semiconductor apparatus comprising:
a semiconductor substrate of a first conductivity type, on a back surface of which a back surface electrode is formed;
a ridge portion that is formed on a front surface of the semiconductor substrate and that has a lower-side clad layer of the first conductivity type, an MQW portion formed on the lower-side clad layer, and an upper-side clad layer of a second conductivity type that is formed on the MQW portion;
a blocking layer that is embedded on the semiconductor substrate on both sides of the ridge portion; and
a contact layer that is formed on the upper-side clad layer that is further formed above the ridge portion and the blocking layer, wherein
in a semiconductor layer that is formed with the semiconductor substrate, the blocking layer, and the contact layer, at least layers of the first conductivity type, the second conductivity type, the first conductivity type, and the second conductivity type are laminated from a lower side,
first two grooves are formed in a composite layer that is formed with layers from the blocking layer to the contact layer, and
the contact layer on the ridge portion and the contact layer interposed between the first two grooves are connected together by a first electrode.

2. A semiconductor apparatus comprising:
a semiconductor substrate of a first conductivity type, on a back surface of which a back surface electrode is formed;
a ridge portion that is formed on a front surface of the semiconductor substrate and that has a lower-side clad layer of the first conductivity type, an MQW portion formed on the lower-side clad layer, and an upper-side clad layer of a second conductivity type that is formed on the MQW portion;
a blocking layer that is embedded on the semiconductor substrate on both sides of the ridge portion; and
a contact layer that is formed on the upper-side clad layer that is further formed above the ridge portion and the blocking layer, wherein
in a semiconductor layer that is formed with the semiconductor substrate, the blocking layer, and the contact layer, at least layers of the first conductivity type, the second conductivity type, the first conductivity type, and the second conductivity type are laminated from a lower side,
first two grooves are formed in a composite layer that is formed with layers from the blocking layer to the contact layer,
second two grooves are formed in the composite layer,
the contact layer on the ridge portion and a first region of the contact layer interposed between the second two grooves are connected together by a first electrode, and
a second region of the contact layer interposed between the second two grooves and the contact layer interposed between the first two grooves are connected together by a second electrode.

3. The semiconductor apparatus according to claim 1, wherein a layer of the first conductivity type or the second conductivity type, the layer constituting the blocking layer, is replaced by an i-type semiconductor layer that is doped with Fe.

4. The semiconductor apparatus according to claim 1, wherein an i-type semiconductor layer is inserted in the blocking layer.

5. The semiconductor apparatus according to claim 2, wherein a layer of the first conductivity type or the second conductivity type, the layer constituting the blocking layer, is replaced by an i-type semiconductor layer that is doped with Fe.

6. The semiconductor apparatus according to claim 2, wherein an i-type semiconductor layer is inserted in the blocking layer.
